(19) United States
(12) Patent Application Publication
(10) Pub. No.: US 2014/0148017 A1
(43) Pub. Date: May 29, 2014

(54) THERMAL TREATMENT METHODS AND APPARATUS

(71) Applicant: Applied Materials, Inc., Santa Clara, CA (US)

(72) Inventors: Bruce E. ADAMS, Portland, OR (US); Stephen MOFFATT, St. Brelade (JE)

(21) Appl. No.: 14/086,773

(22) Filed: Nov. 21, 2013

Related U.S. Application Data
(60) Provisional application No. 61/730,924, filed on Nov. 28, 2012.

(51) Int. Cl. H01L 21/67; H01L 21/324

(52) U.S. Cl. CPC H01L 21/67115; H01L 21/324
USPC 438/795; 392/418

(57) ABSTRACT

Embodiments described herein provide methods and apparatus for thermally treating a substrate. A first radiant energy source that delivers a first radiation at a first fluence and a second radiant energy source that delivers a second radiation at a second fluence are disposed to direct energy toward a substrate support positioned to receive the first radiation at a first location and the second radiation at a second location, wherein the first fluence is 10 to 100 times the second fluence and the first radiation cannot reach the second location. The first radiant energy source may be a laser, and the second radiant energy source may be a plurality of lasers, for example a pulsed laser assembly with a plurality of pulsed lasers. The second radiant energy source may also be a flash lamp. The first and second radiant energy sources may be in the same chamber or different chambers.

### CROSS-REFERENCE TO RELATED APPLICATIONS

This application claims benefit of U.S. Provisional Patent Application Ser. No. 61/730,924, filed Nov. 28, 2012, which is incorporated herein by reference.

### FIELD

Embodiments described herein generally relate to methods and apparatus for thermal treatment of substrates. More specifically, methods and apparatus for annealing semiconductor substrates are described.

### BACKGROUND

Thermal treatment processes are widely used in semiconductor processing. Amorphous semiconductor materials are commonly crystallized using a thermal treatment process that activates movement of atoms into an ordered state from a disordered state, lowering their potential energy and increasing mobility of electrons in the resulting atomic matrix. Band gap of the material is reduced and conductivity increased. Other commonly used processes include annealing of semiconductor materials that may be in a partially disordered crystalline state. The partial disorder frequently results from a doping process that inserts a dopant atom into a crystalline, or mostly crystalline, semiconductor matrix, disrupting, or “damaging”, the crystal structure, reducing the crystallinity of the matrix, and diminishing electrical properties of the material. Annealing the material typically reverses some or all of the damage, substantially recrystallizing the matrix. The dopants are also encouraged to occupy active positions in the crystal matrix, enhancing their contribution to the electrical properties of the material.

As device geometries shrink due to Moore's Law, thermal processing techniques have progressed to treat regions of smaller dimension. Baking wafers, RTP, and spike annealing have been replaced by processes that deliver energy over much shorter durations. This is driven by the need to localize the energy to very small regions of a substrate to avoid diffusion of dopants out of target regions that may be as small as 5,000 nm³ and to avoid thermal disruption of regions surrounding a treatment region. Delivering the desired energy over a very short duration minimizes thermal propagation by radiating much of the energy away before substantial thermal propagation takes place.

Laser annealing processes have become popular ways to deliver large amounts of energy over very short durations. Laser processes have also reached limits recently as the capacity of a semiconductor material to absorb the delivered energy is quickly reached. The absorption properties of silicon are known to change with temperature. However, at the dimensions and durations involved, temperature loses meaning, and the energy balance of individual atoms becomes important. The shrinking dimensions and times severely compress process windows, and new ways of thermally treating substrates are now needed.

### SUMMARY

Embodiments described herein provide an apparatus for thermally treating a substrate, including a first radiant energy source that delivers a first radiation at a first fluence, a first optical assembly optically coupled to the first radiant energy source, a second radiant energy source that delivers a second radiation at a second fluence, a second optical assembly optically coupled the second radiant energy source, and a substrate support positioned to receive the first radiation at a first location and the second radiation at a second location, wherein the first fluence is 10 to 100 times the second fluence and the first radiation cannot reach the second location. The first radiant energy source may be a laser, and the second radiant energy source may be a plurality of lasers, for example a pulsed laser assembly with a plurality of pulsed lasers. The second radiant energy source may also be a flash lamp. The first and second radiant energy sources may be in the same chamber or in different chambers.

Other embodiments described herein provide a method of thermally processing a substrate by selecting a first treatment area on a surface of the substrate, selecting a plurality of second treatment areas on the surface of the substrate that do not overlap with the first treatment area, delivering a first pulse of radiant energy to the first treatment area at a first fluence, and delivering a plurality of radiant energy pulses to the second treatment areas, each pulse at a second fluence that is the same for each of the plurality of radiant energy pulses, wherein the first fluence is 10 to 100 times the second fluence. Each pulse typically has a duration from 1 nsec to 100 nsec. The first pulse of radiant energy typically has a fluence between about 500 mJ/cm² and about 4,000 mJ/cm², which may be sufficient to ablate one or more layers from the substrate. The plurality of radiant energy pulses typically have fluence between about 50 mJ/cm² and about 300 mJ/cm², which may melt portions of the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic view of a thermal processing apparatus according to one embodiment.

FIG. 1B is a top view of a substrate support from the apparatus of FIG. 1A.

FIG. 2 is a schematic view of a thermal processing apparatus according to another embodiment.

### DETAILED DESCRIPTION

The inventors have devised new methods and apparatus for thermal treatment of substrates. Using the new methods and apparatus, a substrate is exposed to a first thermal treatment at a first location and a second thermal treatment at a second location that does not overlap the first location. The first thermal treatment exposes the first location to a first radiant energy at a first fluence and the second thermal treatment exposes the second location to a second radiant energy at a second fluence. The first fluence may be between 10 and 100 times the second fluence.

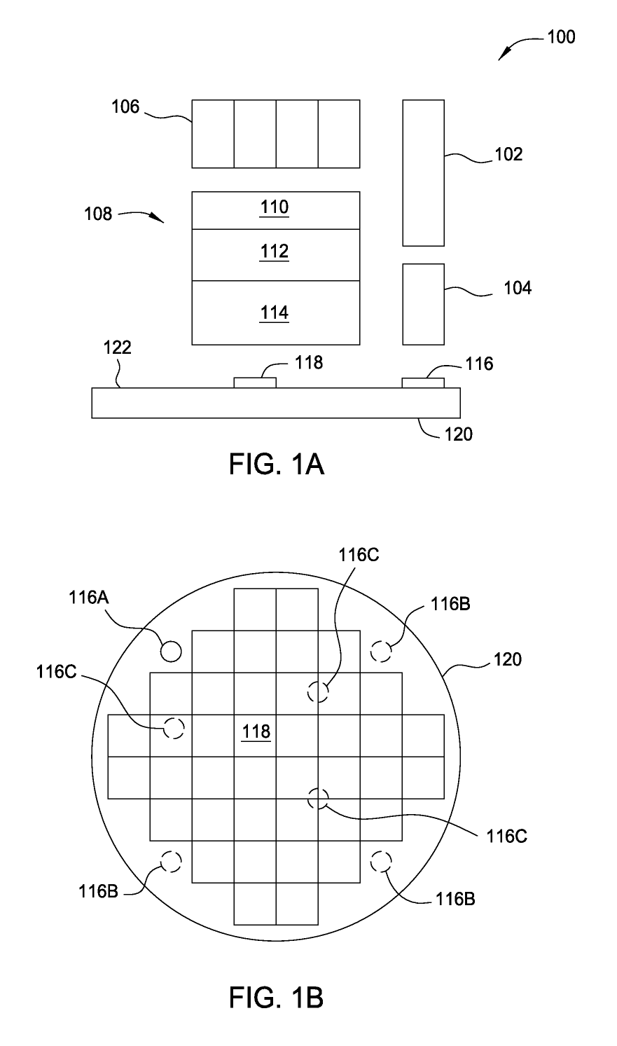

FIG. 1A is a schematic view of a thermal processing apparatus 100 according to one embodiment. The apparatus 100 has a first radiant energy source 102 and a second radiant energy source 106. A first optical assembly 104 is optically coupled to the first radiant energy source 102. A second optical assembly 108 is optically coupled to the second radiant energy source 106. The second optical assembly 108 may comprise a first optical element 110, a second optical element 112, and a third optical element 114 to shape and/or uniformize the energy from the second radiant energy source 106. Each of the first optical element 110, the second optical element 112, and the third optical element 114 may be a pulse combiner, a spatial homogenizer, a temporal homogenizer, a pulse shaper, and/or an edge adjustment member. Multiple such components may be included, and the first optical assembly 104 may have more than three such components. Exemplary pulse combiners, spatial homogenizers, temporal homogenizers, and edge adjustment members are described in commonly owned U.S. patent application Ser. No. 13/194,552, filed Jul. 29, 2011, which is incorporated herein by reference.

A substrate support 120 has a work surface 122 for positioning a substrate to be processed by the apparatus 100. The work surface 122 has a work area that includes a first treatment area 116A and a second treatment area 118. The first treatment area 116A may be at a peripheral location in the work area and the second treatment area 118 may be at a location that is closer to a center of the work area than the first treatment area 116A. FIG. 1B is a top view of the substrate support 120 of the apparatus 100, showing exemplary locations of the first treatment area 116A and the second treatment area 118. In a typical situation, a substrate will be disposed on the work surface 122 of the substrate support 120 and exposed to radiant energy from the first radiant energy source 102 at the first treatment area 116A. The substrate will then be exposed to radiant energy from the second radiant energy source 106 at a succession of second treatment areas 118 as indicated by the rectilinear pattern of treatment areas shown in FIG. 1B.

The first radiant energy source 102 may be one or more lasers that produce a single field of intense radiation directed toward the substrate suppot 120. The first optical assembly 104 may have reflective and refractive components that transform radiant energy emitted by the first radiant energy source 102 in a desired way. For example, the first optical assembly 104 may focus the radiant energy emitted by the first radiant energy source 102 into a small area to increase fluence to a desired level. The first optical assembly 104 may include a combiner if the first radiant energy source 102 has more than one energy emission or optical axis. The first optical assembly 104 may also be omitted, if desired.

The second radiant energy source 106 may be one or more lasers that product a single field of intense radiation or a plurality of intense radiation fields. If more than one laser is used, the second optical assembly 108 may include a combiner to produce a single energy field.

The first radiant energy source 102 typically has a fluence, during operation, that is between 10 and 100 times the fluence of the second radiant energy source 106. The first radiant energy source 102 may emit an energy field at a fluence between about 500 mJ/cm² and about 4,000 mJ/cm², such as between about 1,500 mJ/cm² and about 3,500 mJ/cm², for example about 3,100 mJ/cm². The second radiant energy source 106 may emit an energy field at a fluence between about 50 mJ/cm² and about 300 mJ/cm², such as between about 60 mJ/cm² and about 100 mJ/cm², for example about 70 mJ/cm². The first radiant energy source 102 may be a pulsed laser that emits a pulsed energy field with a pulse duration between about 1 nsec and about 100 nsec, such as between about 10 nsec and about 50 nsec, for example about 25 nsec. The second radiant energy source 106 may emit an energy field that is combined and shaped by the second optical assembly 108 to have a duration between about 1 nsec and about 100 nsec, such as between about 10 nsec and about 50 nsec, for example about 40 nsec, which may also have a temporal profile that is tailored so that the rise and fall in pulse intensity is different from the natural intensity rise and fall produced by the second radiant energy source 106.

The first and second radiant energy sources 102 and 106 may be located in a single chamber or in separate chambers. If located in separate chambers, the first radiant energy source 102 may have a corresponding first substrate support and the second radiant energy source 106 may have a corresponding second substrate support. The first and second substrate supports in such an embodiment would typically have first and second work area, respectively, that have similar dimensions. The first radiant energy source and first substrate support would be positioned such that the first radiant energy source illuminates a first treatment area at a periphery of the first work area, and the second radiant energy source and second substrate support would be positioned such that the second radiant energy source illuminates a plurality of second treatment areas that are closer to a center of the second work area than the first treatment area is to a center of the first work area.

Illumination of the first treatment area 116A may be part of a pre-treatment in which a plurality of pre-treatment areas 116B and 116C are illuminated by the first radiant energy. In such an embodiment, the substrate support 120 may be movable to position each of the pre-treatment areas 116B and 116C, and the first treatment area 116A, proximate to the first radiant energy source 102. Alternately, a divider may be used to divide the first radiant energy among the pre-treatment area 116B and 116C, and the first treatment area 116A. The number and location of the pre-treatment areas 116B and 116C depend on the size and type of substrate to be treated.

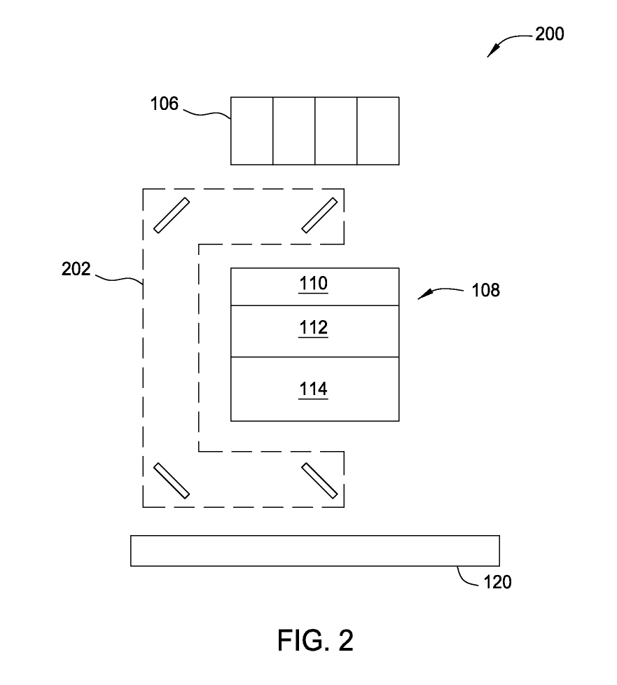

FIG. 2 is a schematic view of a thermal processing apparatus 200 according to another embodiment. The thermal processing apparatus 200 features many of the same components as the thermal processing apparatus 100 of FIG. 1A, which are numbered the same. The thermal processing apparatus 200 features a bypass optic 202 positioned to receive radiant energy emitted by the second radiant energy source 106, route the radiant energy around the second optical assembly 108 and direct the radiant energy toward the substrate support 120. The apparatus 200 of FIG. 2 provides an alternate mode of delivering a first radiant energy to a first treatment area and a second radiant energy to a second treatment area using one source of radiant energy, which may have multiple emitters as described above. The bypass optic 202 may be used to route the emitted energy directly to the work area rather than allowing it to pass through the optical assembly 108. After the first treatment area is illuminated by the high fluence first radiant energy without using the optical assembly 108, the second treatment areas may be illuminated by the low fluence second radiant energy using the optical assembly 108 to uniformize the second radiant energy.

The first radiant energy may be derived from one emitter, for example one laser, of the multi-emitter radiant energy source 106, and the second radiant energy may be derived from one or more, or all, of the emitters of the radiant energy source 106.

The lasers referred to herein may be any type of laser capable of emitting short pulses of intense radiation. The pulses typically have a duration between about 1 nsec and about 100 nsec. To deliver a high fluence pulse, a high power laser having a power rating of about 50 MW or higher may be used. The laser may be a solid state laser, such as a doped YAG laser, which may be switched, power-cycled, or pump-cycled to produce pulses. The low fluence sources may be lower power lasers, or one or more flash lamps may be used. For example, a flash lamp may be used to deliver a fluence of 50-100 mJ/cm² to an entire substrate in one exposure.

Methods of thermally treating a substrate using an apparatus such as those described above include exposing a substrate to a first intense pulse of radiant energy and then exposing the substrate to a second, lower intensity, pulse of radiant energy, where the first intense pulse of radiant energy has a fluence that is 10 to 100 times the fluence of the second, lower intensity, pulse of radiant energy. A first treatment area and a plurality of second treatment areas are selected on a surface of a substrate. The first treatment area may overlap with one or more of the second treatment areas, or the first treatment area may be spaced apart from the second treatment areas such that there is no overlap between the first treatment area and any of the second treatment areas.

The first pulse of radiant energy is delivered to the first treatment area at a first fluence, and a plurality of radiant energy pulses is delivered to the second treatment areas, with each pulse of the plurality of radiant energy pulses having a second fluence that is the same for each of the plurality of radiant energy pulses. One or more of the second treatment areas may each be subjected to more than one of the plurality of radiant energy pulses in a pulse train, each of which may have the same fluence or different fluence, generally in the ranges recited herein. The first fluence is typically 10 to 100 times higher than the second fluence. The first fluence may be between about 500 mJ/cm² and about 4,000 mJ/cm², such as between about 1,500 mJ/cm² and about 3,500 mJ/cm², for example about 3,100 mJ/cm². The second fluence may be between about 50 mJ/cm² and about 300 mJ/cm², such as between about 60 mJ/cm² and about 150 mJ/cm², for example about 70 mJ/cm². The second fluence is repeated in the above range for each of the second treatment areas until all desired portions of the substrate are treated. Surprisingly, in a silicon-on-insulator embodiment, the second fluence may melt and/or ablate portions of the polysilicon layer after pre-treatment using the first fluence.

Substrates that may benefit from such thermal treatment include semiconductor substrates such as silicon-on-insulator substrates featuring a first polysilicon layer, a doped or undoped silicon oxide layer formed on the first polysilicon layer, and a second polysilicon layer formed on the doped or undoped silicon oxide layer. A doped silicon oxide layer may be doped with a dopant such as boron, carbon, phosphorus, arsenic, or a combination of such dopants. The first pulse of radiant energy may have a fluence sufficient to ablate material from the second polysilicon layer in the first treatment area, exposing the silicon oxide layer beneath. Alternately, the second polysilicon layer may be removed by etching in the first treatment area to expose the oxide layer, in which case a lower fluence may be used for the first pulse of radiant energy. Substrates having at least one layer of low refractive index adjacent to a layer of higher refractive index may benefit from a method as described herein, with pulse fluences chosen consistent with the absorption and transmission properties of the materials.

In a silicon-on-insulator embodiment, the radiant energy may be laser energy, particularly for the high fluence exposure, and the lower fluence exposure may be laser energy or flash lamp energy. The first pulse, and each pulse of the plurality of pulses, of radiant energy is typically delivered in a duration less than about 100 nsec, such as between about 1 nsec and about 100 nsec, such as between about 10 nsec and about 50 nsec, for example about 25 nsec. The durations may be the same or different. In one embodiment, the first pulse has a duration of about 25 nsec, while each of the plurality of pulses has a duration of about 40 nsec. Alternately, after the first pulse of radiant energy is delivered, the entire substrate may be exposed at low fluence using a flash lamp in a single exposure.

In an embodiment where a substrate having a first layer, a second layer, and a third layer, and where the first layer is a material having a high refractive index, the second layer is a material having a low refractive index, and the third layer is a material having a high refractive index, an opening may be made in either the first or the third material, and a pulse of radiant energy may be delivered through the opening to the second layer. In such an embodiment, the pulse may be at a fluence below an ablation threshold of the first or the third layer, but above an anneal threshold of the first or the third layer. Delivering the pulse of radiant energy to a low-refractive material disposed between two high-refractive materials causes the pulse to propagate through the low-refractive material exposing a wide area of the first and third layers to radiant energy from the pulse. More than one such opening may be exposed, if desired, to perform a pre-treatment of the substrate surface.

High-angle reflection of the first radiant energy pulse from an interface between the second layer and the first or third layer may be reduced by providing a surface roughness at the interface to disperse the incident radiation laterally. Off-axis reflection from the roughened surface promotes lateral propagation of the radiation through the low-refractive material. Such surface roughness may be provided before the oxide layer is formed by any process known to produce surface roughness, such as sputtering, etching, and the like.

In an embodiment where the entire surface of the substrate is not exposed in a single exposure, the plurality of pulses delivered after the first radiant energy are typically delivered to multiple treatment areas sequentially. The substrate is usually moved with respect to the radiant energy source to deliver the plurality of pulses to all desired treatment areas of the substrate.

In one example, a silicon substrate with a layer of silicon oxide 1,000 Å thick and a layer of polysilicon 1,000 Å thick on the silicon oxide layer was subjected to a pre-treatment laser energy exposure of 3,100 mJ/cm² over an area of 8 mm² for a duration of 27 nsec at each of 144 different locations on the substrate, resulting in ablation of the top polysilicon layer, exposure of the oxide layer beneath, and propagation of the pre-treatment laser energy through the oxide layer. Following the pre-treatment exposure, an anneal process was performed in which successive treatment areas of the substrate were exposed to a laser energy of fluences varying from 50 mJ/cm² to 400 mJ/cm² for a duration of 27 nsec in a first trial and 41 nsec in a second trial. The polysilicon layer above the oxide layer was observed to ablate at a fluence above 100 mJ/cm² following the pre-treatment. Melting was observed at a fluence of 50 mJ/cm².

In a comparative example, a similar silicon-on-insulator substrate was subjected to an anneal process without a high fluence pre-treatment. No ablation of polysilicon was observed at any fluence below 400 mJ/cm² indicating substantially higher melt temperature for substrates not exposed to pre-treatment energy.

While the foregoing is directed to embodiments of the present invention, other and further embodiments of the invention may be devised without departing from the basic scope thereof, and the scope thereof is determined by the claims that follow.

1. An apparatus for thermally treating a substrate, comprising:
a first radiant energy source that delivers a first radiation at a first fluence;
a first optical assembly optically coupled to the first radiant energy source;
a second radiant energy source that delivers a second radiation at a second fluence;
a second optical assembly optically coupled the second radiant energy source; and
a substrate support positioned to receive the first radiation at a first location and the second radiation at a second location, wherein the first fluence is 10 to 100 times the second fluence and the first radiation cannot reach the second location.

2. The apparatus of claim 1, wherein the second radiant energy source is a pulsed laser assembly comprising a plurality of lasers.

3. The apparatus of claim 1, wherein the first radiant energy source is a pulsed laser and the second radiant energy source is a pulsed laser assembly comprising a plurality of lasers.

4. The apparatus of claim 1, wherein the substrate support comprises a work surface, the first location is at a periphery of the work surface, and the second location is closer to a center of the work surface than the first location.

5. The apparatus of claim 2, wherein the second optical assembly comprises a pulse combiner, a pulse shaper, and a homogenizer.

6. The apparatus of claim 2, wherein the second optical assembly comprises a spatial homogenizer, a temporal homogenizer, and an edge adjustment member.

7. The apparatus of claim 3, wherein the first radiant energy source is a laser with a power of at least about 30 MW, a pulse duration no more than 100 nsec., and a beam cross-sectional area no more than 5 cm².

8. The apparatus of claim 3, wherein the first radiant energy source delivers a fluence between about 500 mJ/cm² and about 3,000 mJ/cm², and each laser of the second radiant energy source delivers a fluence between about 50 mJ/cm² and about 300 mJ/cm².

9. The apparatus of claim 4, wherein the first radiant energy source delivers a fluence of between about 500 mJ/cm² and about 3,000 mJ/cm² to the first location and each laser of the second radiant energy source delivers a fluence of between about 50 mJ/cm² and about 300 mJ/cm² to the second location.

10. The apparatus of claim 5, wherein the first radiant energy source is a pulsed laser that delivers a fluence between about 500 mJ/cm2 and about 3,000 mJ/cm2 and the second radiant energy source is a pulsed laser assembly comprising a plurality of lasers delivers a fluence between about 50 mJ/cm² and about 300 mJ/cm², and wherein the substrate support comprises a work surface, the first location is at a periphery of the work surface, and the second location is closer to a center of the work surface than the first location.

11. An apparatus for thermally treating a substrate, comprising:
a first radiant energy source that delivers a first radiation at a first fluence;
a first optical assembly optically coupled to the first radiant energy source;
a first substrate support comprising a first work area positioned to receive the first radiation at a first location at a periphery of the first work area;
a second radiant energy source that delivers a second radiation at a second fluence;
a second optical assembly optically coupled the second radiant energy source; and
a second substrate support comprising a second work area similar in dimension to the first work area and positioned to receive the second radiation at a second location of the second work area that is closer to a center of the second work area than the first location is to a center of the first work area, wherein the first fluence is 10 to 100 times the second fluence.

12. The apparatus of claim 11, wherein the first substrate support is in a first chamber and the second substrate support is in a second chamber.

13. The apparatus of claim 11, wherein the second radiant energy source is a pulsed laser assembly comprising a plurality of lasers.

14. The apparatus of claim 11, wherein the first radiant energy source is a pulsed laser and the second radiant energy source is a pulsed laser assembly comprising a plurality of lasers.

15. The apparatus of claim 13, wherein the second optical assembly comprises a spatial homogenizer, a temporal homogenizer, and an edge adjustment member.

16. The apparatus of claim 15, wherein the first radiant energy source delivers a fluence between about 500 mJ/cm² and about 3,000 mJ/cm², and each laser of the second radiant energy source delivers a fluence between about 50 mJ/cm² and about 300 mJ/cm².

17. A method of thermally processing a substrate, comprising:
selecting a first treatment area on a surface of the substrate having a silicon-on-insulator structure;
selecting a plurality of second treatment areas on the surface of the substrate that do not overlap with the first treatment area;
delivering a first pulse of radiant energy to the first treatment area at a first fluence sufficient to introduce radiant energy into the insulator; and
delivering a plurality of radiant energy pulses to the second treatment areas, each pulse at a second fluence that is the same for each of the plurality of radiant energy pulses, wherein the first fluence is 10 to 100 times the second fluence.

18. The method of claim 17, wherein the first pulse has a fluence between about 500 mJ/cm² and 3,000 mJ/cm² and each pulse of the plurality of radiant energy pulses has a fluence between about 50 mJ/cm² and about 300 mJ/².
